(19) United States
(12) Patent Application Publication
(10) Pub. No.: US 2007/0206424 A1
(43) Pub. Date: Sep. 6, 2007

(54) METHOD FOR ERASING NON-VOLATILE MEMORY

(75) Inventors: Chao-Wei Kuo, Taipei City (TW); Chih-Ming Chao, Hsinchu City (TW); Hann-Ping Hwang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: POWERCHIP SEMICONDUCTOR CORP., Hsinchu (TW)

(21) Appl. No.: 11/531,690

(22) Filed: Sep. 13, 2006

(30) Foreign Application Priority Data
Mar. 6, 2006 (TW) 95107380

(51) Int. Cl. G11C 16/04; G11C 11/34

(52) U.S. Cl. 365/185.29

(57) ABSTRACT

A method for erasing a non-volatile memory is provided. The non-volatile memory includes a first conductive type substrate, a second conductive type well disposed in the first conductive type substrate, a first conductive type well disposed on the second conductive type well, and a memory cell disposed on the first conductive type substrate. The memory cell includes a charge trapping layer and a gate. The erasing method includes the following steps. A first voltage is applied to the gate, a second voltage is applied to the first conductive type substrate, and the second conductive type well is floating. The second voltage is large enough to induce a substrate hot hole effect. The holes are injected into the charge trapping layer by applying the first voltage.

### CROSS-REFERENCE TO RELATED APPLICATION

This application claims the priority benefit of Taiwan application serial no. 95107380, filed Mar. 6, 2006. All disclosure of the Taiwan application is incorporated herein by reference.

### BACKGROUND OF THE INVENTION

1. Field of Invention

The present invention relates to a method for erasing a memory, and more particularly, to a method for erasing a non-volatile memory.

2. Description of Related Art

Among various memory products, non-volatile memory is capable of storing, reading, or erasing data many times, and the data stored therein will not disappear after power-off, and thus it has become a memory device broadly used in personal computers and electronic equipment.

The typical electrically erasable and programmable read only memory has a floating gate and control gate made of doped polysilicon. However, when there are defects in the tunneling oxide layer below the doped polysilicon floating gate, current leakage of the devices easily occurs, thus affecting the reliability of the devices.

Therefore, in conventional technology, a charge trapping layer is used to replace the polysilicon floating gate. The material of the charge trapping layer is, for example, silicon nitride. This silicon nitride charge trapping layer usually has a silicon oxide layer respectively disposed above and below it, forming an oxide-nitride-oxide (ONO) composite layer. This device is usually referred to as a silicon-oxide-nitride-oxide-silicon (SONOS) device. Since silicon nitride has the property of trapping electrons, the electrons injected into the charge trapping layer may concentrate in a part of the charge trapping layer. Therefore, the sensitivity to the defect in the tunneling oxide layer is small, and the current leakage phenomenon of the device will not occur easily.

When data erasing is performed on the SONOS memory, the relative potentials of the substrate, the source/drain region, or the control gate are elevated, and the Fowler-Nordheim (FN) tunneling effect is used to make the electrons be discharged into the substrate or the source/drain from the charge trapping layer after passing through the tunneling dielectric layer.

FIG. 1A is a structural view of a conventional SONOS memory. As shown in FIG. 1A, the SONOS memory includes a P-type substrate 100, a deep N-type well 102 disposed in the P-type substrate 100, a P-type well 104 disposed on the deep N-type well 102, a bottom silicon oxide layer 106, a silicon nitride layer 108, a top silicon oxide layer 110, and a gate 112 sequentially disposed on the P-type substrate 100, a N-type source region 114 and a N-type drain region 116 disposed in the P-type well 104 on both sides of the gate 112. When erasing the memory, the voltage difference between the P-type well 104 (and the deep N-type well 102) and the gate 112 is made to be 8 volts to 20 volts. For example, a voltage of 0 volts is applied to the gate 112, and a voltage of 12 volts is applied to the P-type well 104 (and the deep N-type well 102) respectively, electrons are made to be discharged into the P-type well 104 from the charge trapping layer by using the FN tunneling effect.

However, when the FN tunneling mode is used to erase data in the SONOS memory, the threshold voltage of the SONOS memory decreases with the increass of the erasing time. Since the voltage difference between the gate and the substrate also injects the electrons from the gate into the charge trapping layer, the threshold voltage is gradually made to be in a saturation state, i.e., the so-called erasing saturation phenomenon, and the current density in the tunneling dielectric layer decreases, which extends erasing time and affects device performance.

FIG. 1B shows a schematic view of the relation between the threshold voltage and the erasing time under different voltage differences between the gate and the substrate in a method for erasing a conventional SONOS memory. The method for forming different voltage differences between the gate and the substrate is applying a voltage Vcpw (=8 V) to the P-type well (and the N-type well) and applying different voltages Vg (=0 V, −1 V, −2 V, −3 V, −4 V or −5 V) to the gates respectively. As shown in FIG. 1B, when the voltage Vg applied to the gate is 0 V, −1 V, −2 V or −3 V, since the holes generated to neutralize the electrons in the charge trapping layer are very few, the erasing speed of the FN tunneling effect is extremely slow. When the voltage Vg applied to the gate is −4 V or −5 V, since electrons are injected into the charge trapping layer from the gate, the current density in the tunneling dielectric layer decreases, and it is impossible to make the threshold voltage lower drop to a target value rapidly, thus extending the time spent in erasing operations.

### SUMMARY OF THE INVENTION

An object of the present invention is to provide a method for erasing a non-volatile memory, which reduces the time spent in erasing operations.

Another object of the present invention is to provide a method for erasing a non-volatile memory, which has a preferred reliability.

The present invention provides a method for erasing a non-volatile memory. The non-volatile memory includes a first conductive type substrate, a second conductive type well disposed in the first conductive type substrate, a first conductive type well disposed on the second conductive type well, and a memory cell disposed on the first conductive type substrate. The memory cell includes a charge trapping layer and a gate. The erasing method includes the following steps. A first voltage is applied to the gate, a second voltage is applied to the first conductive type substrate, and the second conductive type well is floating. The second voltage is large enough to induce substrate hot hole effect. The holes are injected into the charge trapping layer by applying the first voltage.

According to an embodiment of the present invention, the first voltage is equal to about 20 volts, and the second voltage is −7 volts.

According to an embodiment of the present invention, the non-volatile memory has a NAND-type array structure.

According to an embodiment of the present invention, the first conductive type is N-type, and the second conductive type is P-type. Alternatively, the first conductive type is P-type, and the second conductive type is N-type. The material of the charge trapping layer is silicon nitride.

The present invention provides a method for erasing a non-volatile memory. The non-volatile memory is provided with a first conductive type substrate, a second conductive type well disposed in the first conductive type substrate, a first conductive type well disposed on the second conductive type well, and a memory cell disposed on the first conductive type substrate. The memory cell includes a charge trapping layer and a gate. The erasing method includes the following steps. A first voltage is applied to the gate, and a second voltage is applied to the first conductive type substrate. The second conductive type well and the first conductive type well constitute a Zener diode. The second voltage is large enough to break down the Zener diode and induce substrate hot hole effect. The holes are injected into the charge trapping layer by applying the first voltage.

According to an embodiment of the present invention, the first voltage is 5 volts, and the second voltage is −7 volts.

According to an embodiment of the present invention, the non-volatile memory has a NAND-type array structure.

According to an embodiment of the present invention, the first conductive type is N-type, and the second conductive type is P-type. Alternatively, the first conductive type is P-type, and the second conductive type is N-type. The material of the charge trapping layer is silicon nitride.

The present invention provides a method for erasing the non-volatile memory. The non-volatile memory is provided with a first conductive type substrate, a second conductive type well disposed in the first conductive type substrate, a first conductive type well disposed on the second conductive type well, and a memory cell disposed on the first conductive type substrate. The memory cell includes a charge trapping layer and a gate. The erasing method includes the following steps. A first voltage is applied to the gate, and a second voltage is applied to the first conductive type substrate, and a third voltage is applied to the second conductive type well. The first conductive type substrate, the second conductive type well, and the first conductive type well constitute a bipolar transistor. The third voltage is large enough to turn on the bipolar transistor, and the second voltage is large enough to induce substrate hot hole effect. The holes are injected into the charge trapping layer by applying the first voltage.

According to an embodiment of the present invention, the first voltage is 5 volts, the second voltage is −7 volts, and the third voltage is 1 volt.

According to an embodiment of the present invention, the non-volatile memory has a NAND-type array structure.

According to an embodiment of the present invention, the first conductive type is N-type, and the second conductive type is P-type. Alternatively, the first conductive type is P-type, and the second conductive type is N-type.

According to an embodiment of the present invention, the material of the charge trapping layer includes silicon nitride.

In the erasing method of the present invention, the erasing time is reduced due to the use of the substrate hot hole effect for erasing the memory, thus improving the operating speed of the memory.

Moreover, the erasing speed is not affected by the thickness of the bottom dielectric layer due to the use of the mechanism of injecting the hot holes into the charge trapping layer. Therefore, the thickness of the bottom dielectric layer is increased, and the current leakage of the memory is avoided, thus improving the data storage effect.

Furthermore, this erasing method does not need to change the structure or process of the memory; therefore it can be applied to conventional SONOS memories directly.

In order to the make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a structural view of a conventional SONOS memory.

FIG. 1B shows a schematic view of the relation between the threshold voltage and the erasing time under different voltage differences between the gate and the substrate in a method for erasing a conventional SONOS memory.

FIG. 2A is a schematic sectional view of an embodiment according to the method for erasing a non-volatile memory of the present invention.

FIG. 2B is a simplified circuit diagram of FIG. 2A.

FIG. 3A is a schematic sectional view of another embodiment according to the method for erasing the non-volatile memory of the present invention.

FIG. 3B is a simplified circuit diagram of FIG. 3A.

FIG. 4A is a schematic sectional view of yet another embodiment according to the method for erasing a non-volatile memory of the present invention.

FIG. 4B is a simplified circuit diagram of FIG. 4A.

FIG. 5A shows a schematic view of the relation between the read current and the accumulative proportion of the non-volatile memory.

FIG. 5B shows a schematic view of the relation between the threshold voltage and the count value of the non-volatile memory.

FIG. 6 is a structural sectional view of a NAND-type non-volatile memory.

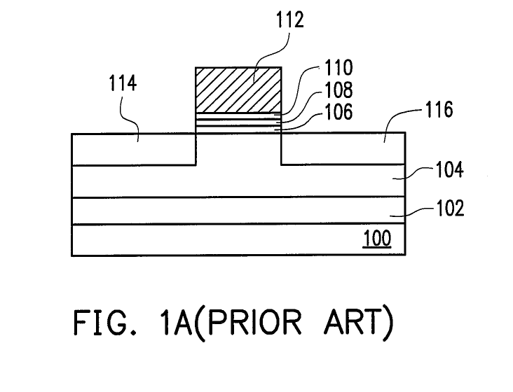

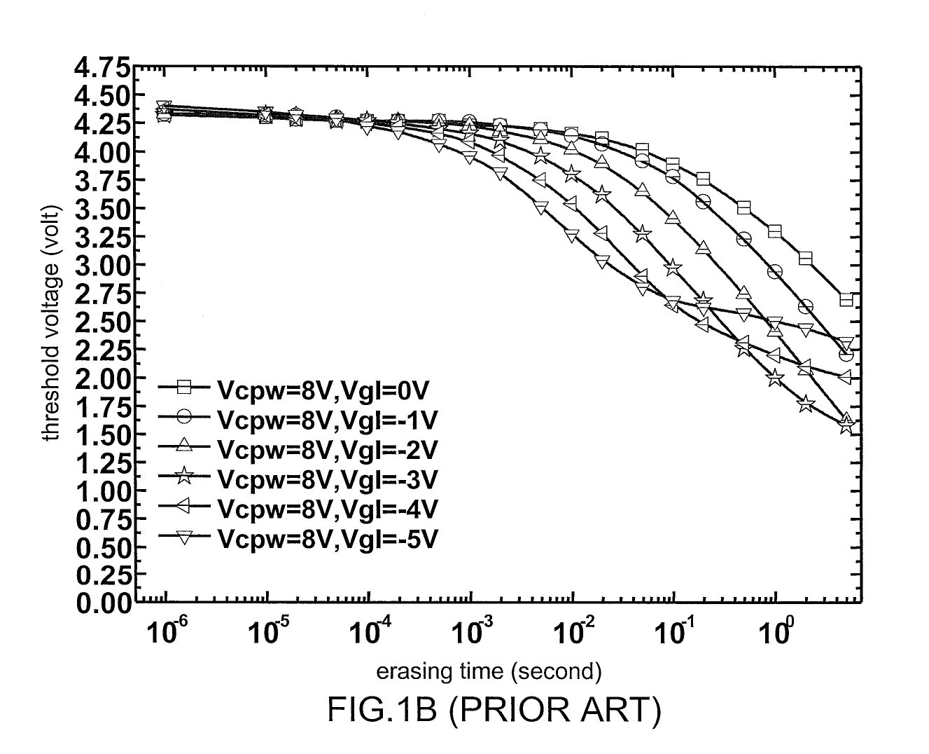

### DESCRIPTION OF EMBODIMENTS

### First Embodiment

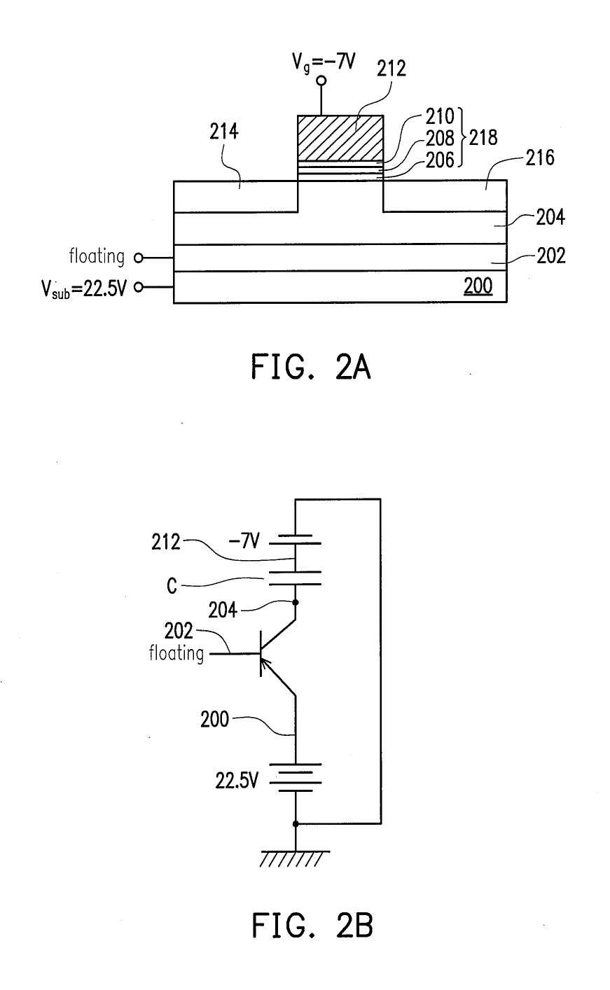

FIG. 2A is a schematic sectional view of an embodiment according to the method for erasing a non-volatile memory of the present invention. FIG. 2B is a simplified circuit diagram of FIG. 2A.

As shown in FIG. 2A, the non-volatile memory includes a first conductive type substrate 200, a second conductive type well 202, a first conductive type well 204, a bottom dielectric layer 206, a charge trapping layer 208, a top dielectric layer 210, a gate 212, a second conductive type source region 214, and a second conductive type drain region 216.

The second conductive type well 202 is, for example, disposed in the first conductive type substrate 200. The first conductive type well 204 is, for example, disposed on the second conductive type well 202. The bottom dielectric layer 206, the charge trapping layer 208, the top dielectric layer 210, and the gate 212 are, for example, disposed sequentially on the first conductive type substrate 200. The material of the bottom dielectric layer 206 and the top dielectric layer 210 is, for example, silicon oxide. The material of the charge trapping layer 208 is, for example, a charge trapping material, such as silicon nitride. The bottom dielectric layer 206, the charge trapping layer 208, and the top dielectric layer 210, for example, constitute a composite dielectric layer 218. The second conductive type source region 214 and the second conductive type drain region 216, for example, are disposed in the first conductive type well 204 on both sides of the gate 212. The first conductive type is N-type, and the second conductive type is P-type. Alternatively, the first conductive type may be P-type, in which case the second conductive type is N-type.

As shown in FIG. 2B, the first conductive type substrate 200, the second conductive type well 202, and the first conductive type well 204 constitute a bipolar transistor. The gate 212, the composite dielectric layer 218, the first conductive type well 204 constitute a capacitor C.

Referring to FIG. 2A and FIG. 2B, when erasing operation is performed on the non-volatile memory, a voltage Vg is applied to the gate 212, a voltage V_{sub} is applied to the first conductive type substrate 200, and the second conductive type well 202 is floating. The breakdown must be generated among the first conductive type substrate 200, the second conductive type well 202, and the first conductive type well 204 to induce substrate hot hole effect by applying the V_{sub}, therefore V_{sub} must be larger than or equal to 20 volts, for example about −22.5 volts. When breakdown is generated among the first conductive type substrate 200, the second conductive type well 202, and the first conductive type well 204, the generated hot holes pass through the second conductive type well 202 and the first conductive type well 204 at an accelerated speed, then the holes are injected into the charge trapping layer 208 by the voltage Vg applied to the gate 212, so as to neutralize the electrons in the charge trapping layer 208. The voltage Vg, for example, is about −7 volts.

In the erasing method of the present invention, the erasing time is reduced due to the use of the substrate hot hole effect for erasing the memory, thus improving the operating speed of the memory. Moreover, the erasing speed is not affected by the thickness of the bottom dielectric layer due to the use of the mechanism of injecting the hot holes into the charge trapping layer. Therefore, the thickness of the bottom dielectric layer is increased, and the current leakage of the memory is avoided, thus improving the data storage effect. Furthermore, this erasing method does not need to change the structure or process of the memory, and therefore can be applied to conventional SONOS memories directly.

### Second Embodiment

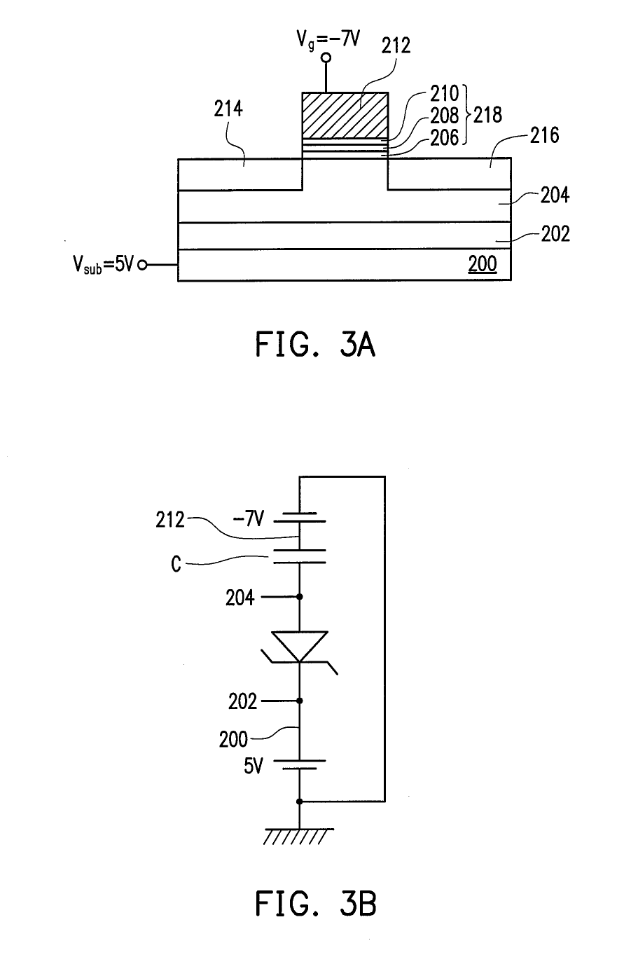

FIG. 3A is a schematic sectional view of another embodiment according to the method for erasing the non-volatile memory of the present invention. FIG. 3B is a simplified circuit diagram of FIG. 3A. The members in FIG. 3A that are the same as those in FIG. 2A are represented with the same labels and description thereof is omitted. Description of the differences is made herein.

As shown in FIG. 3, the second conductive type well 202 and the first conductive type well 204 constitute a Zener diode. Therefore, the second conductive type well 202 and the first conductive type well 204 have a relative high dopant concentration. For example, the dopant concentration of the conventional second conductive type well 202 and the first conductive type well 204 is generally about 5E12/cm². In the present invention, in order to make the second conductive type well 202 and the first conductive type well 204 constitute the Zener diode, the dopant concentration of the second conductive type well 202 and the first conductive type well 204 is elevated to about 5E13/cm²-1E14/cm², which is about 10-100 times of the conventional dopant concentration. The gate 212, the composite dielectric layer 218, and the first conductive type well 204 constitute the capacitor C.

Referring to FIG. 3A and FIG. 3B, when erasing operation is performed on the non-volatile memory, a voltage Vg is applied to the gate 212, and a voltage V_{sub} is applied to the first conductive type substrate 200. The Zener diode must be breakdown to induce the substrate hot hole effect by applying V_{sub}; therefore the V_{sub} is, for example, about 5 volts. When the Zener diode is breakdown, the generated hot holes pass through the Zener diode at an accelerated speed and reach the first conductive type well 204, then the holes are injected into the charge trapping layer 208 by the voltage Vg applied to the gate 212, so as to neutralize the electrons in the charge trapping layer 208. The voltage Vg, for example, is about −7 volts.

In the erasing method of the present invention, the erasing time is reduced due to the use of the substrate hot hole effect for erasing the memory, thus improving the operating speed of the memory. Moreover, the erasing speed is not affected by the thickness of the bottom dielectric layer due to the use of the mechanism of injecting the hot holes into the charge trapping layer. Therefore, the thickness of the bottom dielectric layer is increased, and the current leakage of the memory is avoided, thus improving the data storage effect. Furthermore, in comparison with the first embodiment, the embodiment does not need to apply a relative high bias to the first conductive type substrate, therefore device performance is improved.

### Third Embodiment

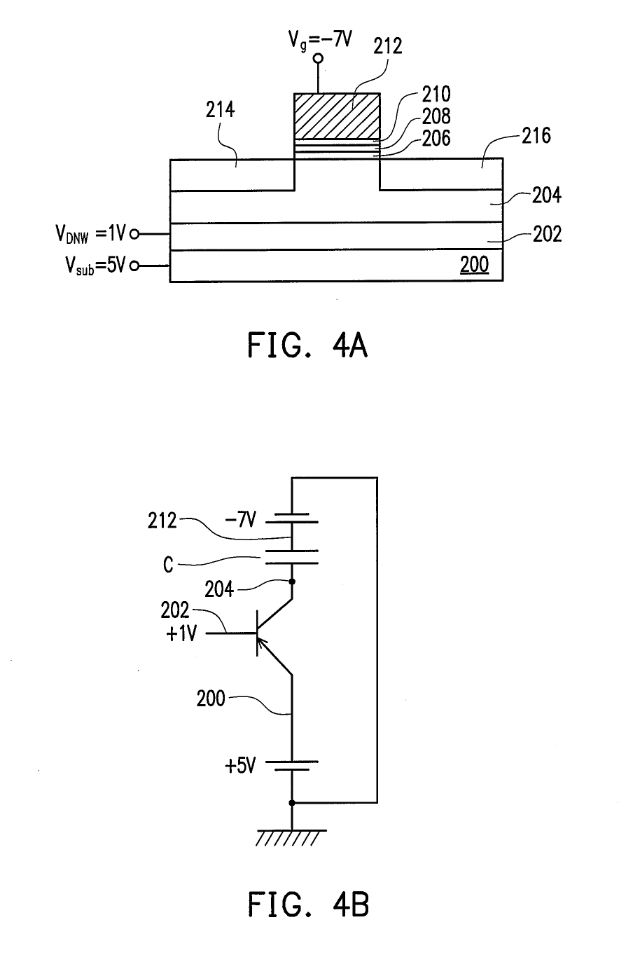

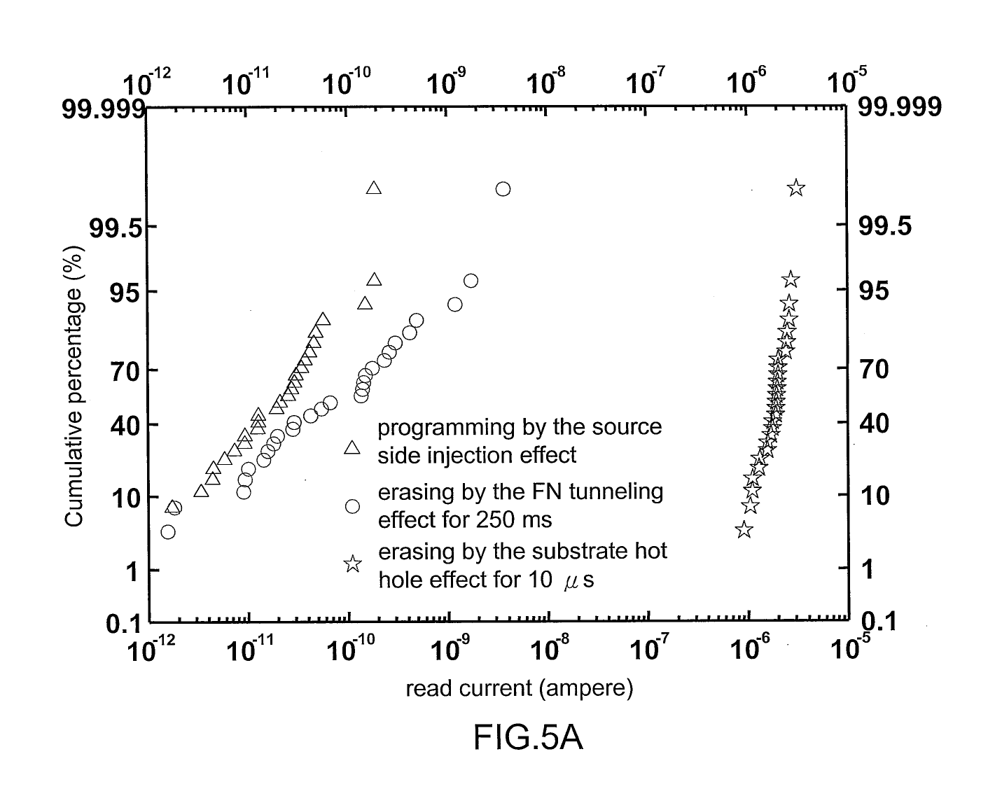

FIG. 4A is a schematic sectional view of another embodiment according to the method for erasing a non-volatile memory of the present invention. FIG. 4B is a simplified circuit diagram of FIG. 4A. The members in FIG. 4A that are the same as those in FIG. 2A are represented with the same labels and description thereof is omitted. Description of the differences is made herein.

As shown in FIG. 4B, the first conductive type substrate 200, the second conductive type well 202, and the first conductive type well 204 constitute a bipolar transistor. The gate 212, the composite dielectric layer 218, the first conductive type well 204 constitute the capacitor C.

Referring to FIG. 4A and FIG. 4B, when erasing operation is performed on the non-volatile memory, a voltage Vg is applied to the gate 212, a voltage V_{sub} is applied to the first conductive type substrate 200, and a voltage V_{DNW} is applied to the second conductive type well 202. The V_{sub} is large enough to induce the substrate hot hole effect, and the V_{sub} is, for example, about 5 volts. The voltage V_{DNW} is large enough to turn on the bipolar transistor, and the V_{sub} is, for example, about 1 volt. When the bipolar transistor is turned on, the generated hot holes pass through the bipolar transistor at an accelerated speed, then the holes are injected into the charge trapping layer 208 by the voltage Vg applied to the gate 212, so as to neutralize the electrons in the charge trapping layer 208. The voltage Vg, for example, is about −7 volts.

In the erasing method of the present invention, the erasing time is reduced due to the use of the substrate hot hole effect for erasing the memory, thus improving the operating speed of the memory. Moreover, the erasing speed is not affected by the thickness of the bottom dielectric layer due to the use of the mechanism of injecting the hot holes into the charge trapping layer. Therefore, the thickness of the bottom dielectric layer is increased, and the current leakage of the memory is avoided, thus improving the data storage effect. Furthermore, this erasing method does not need to change the structure or process of the memory; therefore it may be applied to conventional SONOS memories directly. In addition, in comparison with the first embodiment, the embodiment does not need to apply a relative high bias to the first conductive type substrate, therefore device performance is improved.

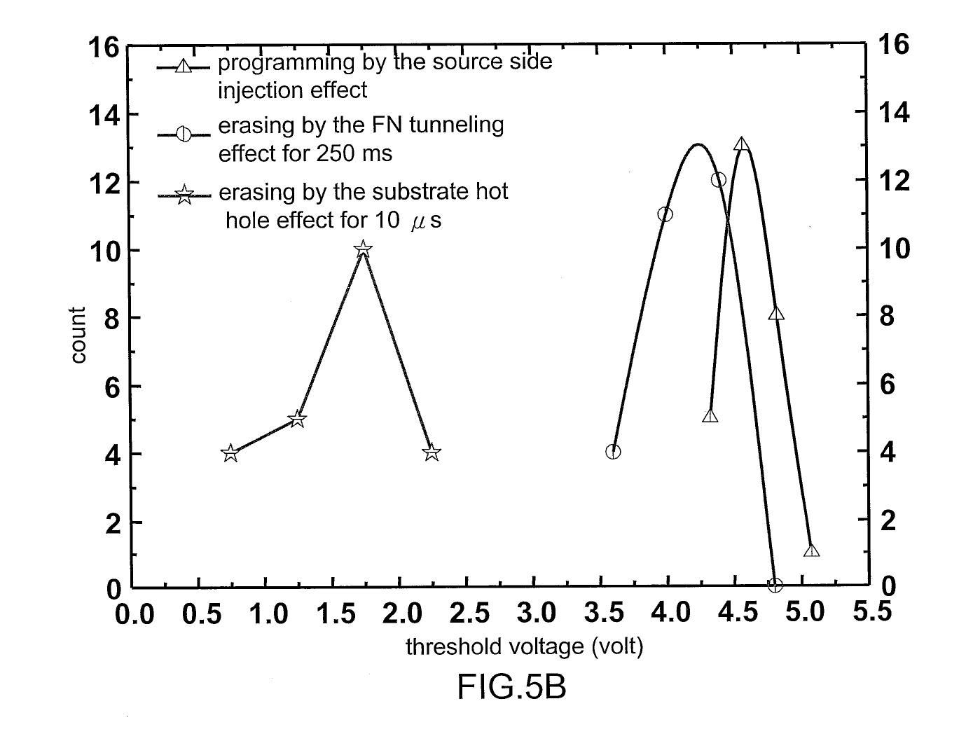

FIG. 5A shows a schematic view of the relation between the read current and the cumulative percentage of the non-volatile memory. FIG. 5B shows a schematic view of the relation between the threshold voltage and the count value of the non-volatile memory.

As shown in FIG. 5A, after the memory is programmed with the source side injection effect, the read operation is performed on the memory, and the measured read current is at the minimum. After the memory is erased by FN tunneling effect for 250 milliseconds, the read operation is performed on the memory, and the measured read current is larger than that of the programmed memory. However, the read current of the programmed memory is about 10 times less than that of the memory erased by FN tunneling effect. When the memory is erased with the substrate hot hole effect for 10 microseconds, the read operation is performed on the memory, and the measured read current is larger than that of the memory erased by FN tunneling effect. Moreover, the read current of the memory may be increased rapidly by erasing the memory with the substrate hot hole effect for only 10 microseconds. The read current of the memory erased with the substrate hot hole effect is about 10⁵ times of that of the memory erased by FN tunneling effect. Therefore, it can be known from the result in FIG. 5A that in comparison with conventional method for erasing by FN tunneling effect, the erasing method of the present invention has a faster speed of erasing the memory.

As such, as shown in FIG. 5B, after the memory is programmed with the source side injection effect, the threshold voltage of the memory is measured and the measured threshold voltage is at the maximum. After the memory is erased by FN tunneling effect for 250 milliseconds, the threshold voltage of the memory is measured and the measured threshold voltage of the memory is smaller than that of the programmed memory. When the memory is erased with the substrate hot hole effect for 10 microseconds, the threshold voltage of the memory is measured and the measured threshold voltage of the memory is smaller than that of the memory erased by FN tunneling effect. Moreover, the threshold voltage of the memory may be decreased rapidly by erasing the memory with the substrate hot hole effect for only 10 microseconds. The threshold voltage of the memory erased with the substrate hot hole effect is less than about 0.5 times of the threshold voltage of the memory erased by FN tunneling effect. Therefore, it can be known from the result in FIG. 5B that in comparison with conventional method for erasing by FN tunneling effect, the erasing method of the present invention has a faster speed of erasing the memory.

Moreover, in the first to the third embodiments, a single memory cell is illustrated as an example. However, the erasing method of the present invention is suitable for the non-volatile memory with the NAND array structure.

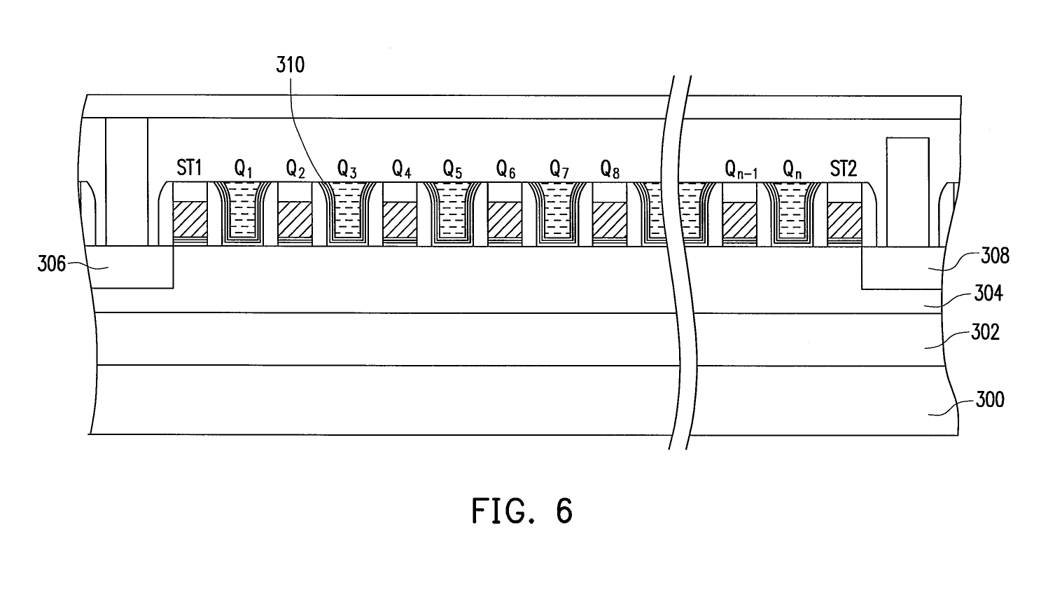

FIG. 6 is a structural sectional view of a NAND-type non-volatile memory.

Referring to FIG. 6, the non-volatile memory structure at least includes a first conductive type substrate 300, a second conductive type well 302, a first conductive type well 304, a plurality of memory cell structures Q1-Qn, selecting units ST1 and ST2, a drain region 306, and a source region 308.

The second conductive type well 302, for example, is disposed in the first conductive type substrate 300. The first conductive type well 304, for example, is disposed on the second conductive type well 302. The plurality of memory cell structures Q1-Qn and the selecting units ST1 and ST2 are disposed on the substrate 300 in gapless series connection with each other, forming a memory cell row. Moreover, the plurality of memory cell structures Q1-Qn and the selecting units ST1 and ST2 each is provided with a charge trapping layer 310. The drain region 306 and the source region 308 are respectively disposed in the substrate on both sides of the memory cell row.

When the NAND-type non-volatile memory is to be erased, the method of the third embodiment is taken as an example. A voltage of −7 volts is applied to the gates of the memory cell structures Q1-Qn and the selecting units ST1 and ST2; a voltage of 5 volts is applied to the first conductive type substrate 300; a voltage of 1 volt is applied to the second conductive type well 302, so as to induce the substrate hot hole effect, and inject the holes into the charge trapping layers 310 of the memory cell structures Q1-Qn and the selecting units ST1 and ST2 to neutralize the electrons in the charge trapping layer 310, thus erasing the whole memory cell row.

Of course, the erasing methods of the first embodiment and the second embodiment of the present invention are also applicable to the NAND-type non-volatile memory as shown in FIG. 6.

To sum up, in the erasing method of the present invention, the erasing time is reduced due to the use of the substrate hot hole effect for erasing the memory, thus improving the operating speed of the memory.

Moreover, the erasing speed of the substrate hot hole effect is not affected by the thickness of the bottom dielectric layer due to the use of the mechanism of injecting the hot holes into the charge trapping layer. Therefore, the thickness of the bottom dielectric layer is increased, and the current leakage of the memory is avoided, thus improving the data storage effect.

Furthermore, this erasing method does not need to change the structure or process of the memory; therefore it may be applied to conventional SONOS memory directly.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for erasing a non-volatile memory, wherein the non-volatile memory includes a first conductive type substrate, a second conductive type well disposed in the first conductive type substrate, a first conductive type well disposed on the second conductive type well, and a memory cell comprising a charge trapping layer and a gate disposed on the first conductive type substrate, the method comprising:
applying a first voltage to the gate, applying a second voltage to the first conductive type substrate, and floating the second conductive type well, wherein the second voltage is large enough to induce substrate hot hole effect, and holes are injected into the charge trapping layer by applying the first voltage.

2. The method of claim 1, wherein the first voltage is larger than or equal to 20 volts, and the second voltage is −7 volts.

3. The method of claim 1, wherein the non-volatile memory has a NAND-type array structure.

4. The method of claim 1, wherein the first conductive type is N-type, and the second conductive type is P-type.

5. The method of claim 1, wherein the first conductive type is P-type, and the second conductive type is N-type.

6. The method of claim 1, wherein the material of the charge trapping layer comprises silicon nitride.

7. A method for erasing a non-volatile memory, wherein the non-volatile memory includes a first conductive type substrate, a second conductive type well disposed in the first conductive type substrate, a first conductive type well disposed on the second conductive type well, and a memory cell comprising a charge trapping layer and a gate disposed on the first conductive type substrate, the method comprising:
applying a first voltage to the gate, and applying a second voltage to the first conductive type substrate, wherein the second conductive type well and the first conductive type well constitute a Zener diode, the second voltage is large enough to breakdown the Zener diode and induce substrate hot hole effect, and holes are injected into the charge trapping layer by applying the first voltage.

8. The method of claim 7, wherein the first voltage is 5 volts, and the second voltage is −7 volts.

9. The method of claim 7, wherein the non-volatile memory has a NAND-type array structure.

10. The method of claim 7, wherein the first conductive type is N-type, and the second conductive type is P-type.

11. The method of claim 7, wherein the first conductive type is P-type, and the second conductive type is N-type.

12. The method of claim 7, wherein the material of the charge trapping layer comprises silicon nitride.

13. A method for erasing a non-volatile memory, wherein the non-volatile memory includes a first conductive type substrate, a second conductive type well disposed in the first conductive type substrate, a first conductive type well disposed on the second conductive type well, and a memory cell comprising a charge trapping layer and a gate disposed on the first conductive type substrate, comprising:
applying a first voltage to the gate, applying a second voltage to the first conductive type substrate, and applying a third voltage to the second conductive type well, wherein the first conductive type substrate, the second conductive type well, and the first conductive type well constitute a bipolar transistor, the third voltage is large enough to turn on the bipolar transistor, the second voltage is large enough to induce substrate hot hole effect, and holes are injected into the charge trapping layer by applying the first voltage.

14. The method of claim 13, wherein the first voltage is 5 volts, the second voltage is −7 volts, and the third voltage is 1 volt.

15. The method of claim 13, wherein the non-volatile memory has a NAND-type array structure.

16. The method of claim 13, wherein the first conductive type is N-type, and the second conductive type is P-type.

17. The method of claim 13, wherein the first conductive type is P-type, and the second conductive type is N-type.

18. The method of claim 13, wherein the material of the charge trapping layer comprises silicon nitride.
